(19) United States
(12) Patent Application Publication
(10) Pub. No.: US 2015/0144964 A1
(43) Pub. Date: May 28, 2015

(54) SILICON CARBIDE EPI-WAFER AND METHOD OF FABRICATING THE SAME

(71) Applicant: LG INNOTEK CO., LTD., Seoul (KR)

(72) Inventors: SeokMin Kang, Seoul (KR); Jihye Kim, Seoul (KR); Ickchan Kim, Seoul (KR)

(73) Assignee: LG Innotek Co., Ltd., Seoul (KR)

(21) Appl. No.: 14/404,467

(22) PCT Filed: May 30, 2013
(86) PCT No.: PCT/KR2013/004754

§ 371 Date: Nov. 27, 2014

(30) Foreign Application Priority Data
May 30, 2012 (KR) 10-2012-0057179

(51) Int. Cl. H01L 29/16

(52) U.S. Cl. CPC H01L 29/1608
USPC 257/77

(57) ABSTRACT

A method of fabricating an epi-wafer includes providing a wafer in a susceptor, performing a surface treatment on the wafer by heating the susceptor and supplying a surface treatment gas, and growing an epi-layer on the wafer. An epi-wafer includes a wafer, and an epi-layer formed on the wafer. Surface defects of the wafer are 0.5 ea/cm² or less.

### TECHNICAL FIELD

The present invention relates to a silicon carbide epi-wafer and a method of fabricating the same.

### BACKGROUND ART

Generally, among technology for forming various thin films on a substrate or a wafer, a chemical vapor deposition (CVD) method has been widely used The CVD method is a deposition technique accompanied by a chemical reaction, in which a semiconductor thin film or an insulating layer may be formed on a surface of a wafer using a chemical reaction of a source material.

Such a CVD method and a CVD deposition apparatus have attracted attention as an important technology for forming a thin film due to reduction in size of semiconductor devices and development of high efficiency and high power LEDs. The CVD method and the CVD deposition apparatus are currently used to deposit various thin films such as a silicon layer, an oxide layer, a silicon nitride layer, or silicon oxynitride layer on a wafer.

For example, in order to deposit a silicon carbide thin film on a substrate or a wafer, a reaction gas capable of reacting with the wafer needs to be supplied. Conventionally, a silicon carbide epi-layer is deposited by supplying a gas material, such as a standard precursor like silane (SiH₄) or ethylene (C₂H₄) a, or a liquid material such as methyltrichlorosilane (MTS), heating the material to generate an intermediate compound, such as CH₃ or SiClₓ, and supplying the intermediate compound into a deposition unit to react the intermediate compound with a wafer disposed in a susceptor.

However, when the epi-layer is deposited on the silicon carbide, problems such as defects or surface roughness may be generated on the wafer. The defects or the surface roughness of the wafer may degrade quality of the silicon carbide epi-wafer.

Accordingly, a silicon carbide epi-wafer capable of solving the problems such as defects or surface roughness, and a method of fabricating the silicon carbide epi-wafer need to be developed.

### DISCLOSURE

### Technical Problem

The present invention is directed to a method of fabricating an epi-wafer by which a high quality silicon carbide epi-wafer is fabricated by reducing surface defects and surface roughness of a wafer, and an epi-wafer fabricated by the method.

### Technical Solution

According to an aspect of the present invention, there is provided a method of fabricating an epi-wafer including providing a wafer in a susceptor, performing a surface treatment on the wafer, and growing an epi-layer on the wafer.

According to another aspect of the present invention, there is provided an epi-wafer including a wafer, and an epi-layer formed on the wafer. Surface defects of the wafer are 0.5 ea/cm² or less.

### Advantageous Effects

In the method of fabricating an epi-wafer according to the embodiment of the present invention, a surface treatment process may be carried out on the wafer before growing an epi-layer.

Accordingly, surface defects of the wafer may be reduced and surface roughness may be improved by performing the surface treatment process on the wafer. That is, unstable silicon atoms on the surface of the wafer may be suppressed by performing the surface treatment process on the wafer. Silicon atoms on the surface of the silicon carbide bulk wafer may form protrusions on the surface of the wafer and roughen the surface of the silicon carbide wafer. Such surface roughness may cause generation of defects on the silicon carbide wafer, and the defects may remain when a silicon carbide epi-layer is deposited on the silicon carbide wafer and affect the silicon carbide epi-layer.

Accordingly, since unstable Si atoms may be suppressed by an etching process using the surface treatment gas in the method of fabricating an epi-wafer according to the embodiment of the present invention, surface defects, step bunching, or surface roughness generated when the epi-layer is grown on the wafer may be reduced. Accordingly, a high quality silicon carbide epi-wafer may be fabricated by the method of fabricating an epi-wafer according to the embodiment of the present invention.

In addition, since the surface defects of the silicon carbide epi-wafer are reduced to less than 0.5 ea/cm² and the surface roughness is reduced to less than 1 nm, the silicon carbide epi-wafer according to the embodiment of the present invention may be used as an electronic material having high quality and high efficiency.

### DESCRIPTION OF DRAWINGS

The above and other objects, features, and advantages of the present invention will become more apparent to those of ordinary skill in the art by describing in detail exemplary embodiments thereof with reference to the accompanying drawings, in which:

FIG. 1 is a process flowchart for describing a method of fabricating an epi wafer according to an embodiment of the present invention;

FIG. 2 is an exploded perspective view of a deposition apparatus according to an embodiment of the present invention;

FIG. 3 is a perspective view of a deposition apparatus according to an embodiment of the present invention;

FIG. 4 is a part of a cross-sectional view taken along line I-I′ of FIG. 3;

FIGS. 5 to 9 are SEM photographs of epi-wafers fabricated according to embodiments of the present invention and a comparative example.

### MODE FOR INVENTION

Exemplary embodiments of the present invention will be described in detail below with reference to the accompanying drawings. While the present invention is shown and described in connection with exemplary embodiments thereat it will be apparent to those skilled in the art that various modifications can be made without departing from the spirit and scope of the invention.

It will be understood that when a layer, region, pattern, or structure is referred to as being “on” another layer, region, pattern, or structure, it can be directly on the other element or intervening elements may be present. Spatially relative terms, such as “beneath,” “below,” “lower,” “above,” “upper,” and the like may be used herein to describe the relationship of one element or feature to another, as illustrated in the drawings.

In the drawings, the thicknesses or sizes of layers, regions, patterns, or structures may be modified for clarity and convenience of description.

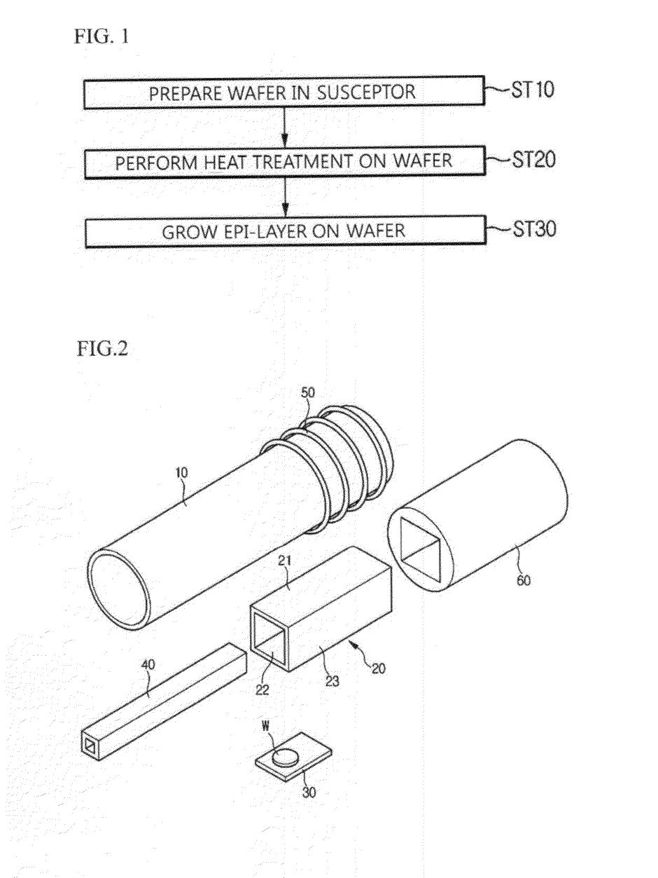

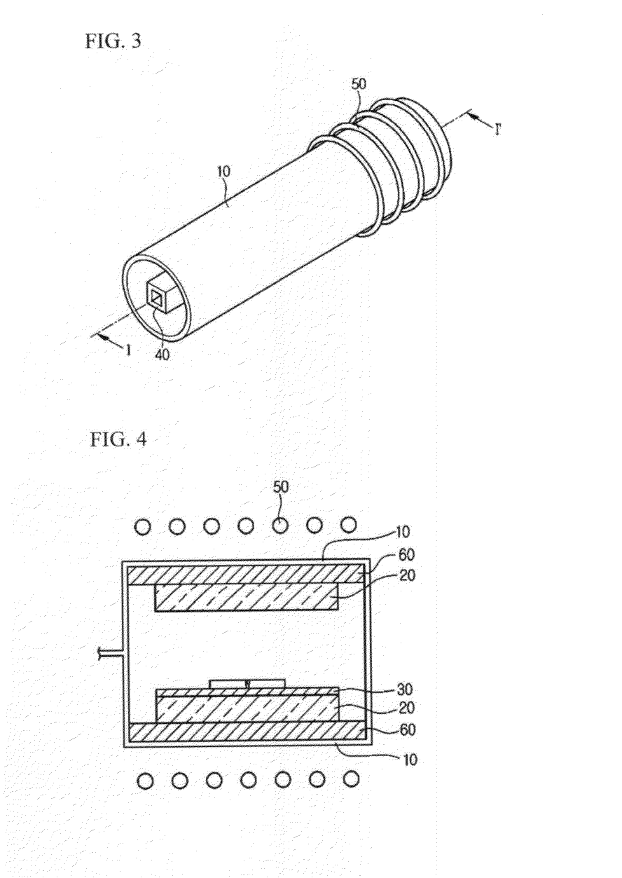

Hereinafter, a method of fabricating an epi-wafer according to an embodiment of the present invention will be described with, reference to FIGS. 1 to 4.

FIG. 1 is a process flowchart for describing a method of fabricating an epi wafer according to an embodiment of the present invention, and FIGS. 2 to 4 are respectively an exploded perspective view, a perspective view, and a cross-sectional view of a susceptor, for describing a method of fabricating an epi-wafer according to an embodiment of the present invention.

Referring to FIG. 1, the method of fabricating an epi-wafer according to the embodiment of the present invention includes providing a wafer in a susceptor (ST10), performing a surface treatment on the wafer (ST20), and growing an epi-layer on the wafer (ST30).

In a process of providing a wafer in the susceptor (ST10), the wafer may be disposed in the susceptor disposed in a chamber. Here, the wafer may be a silicon carbide wafer. That is, the method of fabricating an epi-wafer according to the embodiment of the present invention may be a method of fabricating a silicon carbide epi-wafer. More specifically, the wafer may be 4H-silicon carbide and have an off angle in the range of 3° to 10°. Here, the off angle may be defined as an inclination angle of a wafer with respect to a (0001) Si plane and a (000-1) C plane.

Next, in the process of performing the surface treatment on the wafer (ST20), a surface of the wafer may be etched using a surface treatment gas.

More specifically, the process of performing the surface treatment on the wafer (ST20) may include supplying the surface treatment gas into the susceptor, and heating the susceptor.

The surface treatment gas supplied into the susceptor may be a compound including hydrogen (H) and chlorine (Cl). More preferably, the surface treatment gas may be hydrogen chloride (HCl). More specifically, the surface of the wafer may be subjected to a heat treatment by being etched using HCl. However, embodiments of the present invention are not limited thereto, sand various surface treatment gases including H and Cl may be used to etch the surface of the wafer.

Here, a flow rate of the surface treatment gas may be about 100 ml/min or more. More preferably, the flow rate of the surface treatment gas may be about 100 ml/min to about 500 ml/min. That is, the HCl gas may be supplied into the susceptor at the flow rate of about 100 ml/min to about 500 ml/min. The range of the flow rate of the surface treatment gas may be set in consideration of an etch degree of the wafer by the surface treatment. That is, when the flow rate of the surface treatment gas is beyond the range of about 100 ml/min to about 500 ml/min, it may be difficult to control surface defects and/or surface roughness while the epi-layer is grown after the surface treatment.

When the surface treatment gas is supplied into the susceptor, the surface of the wafer may be heated by heating the susceptor. The heating temperature may be about 1500° C. or more. More preferably, the heating temperature of the susceptor may be in the range of about 1500° C. to about 1600° C. That is, the process of etching the surface of the wafer by the surface treatment gas may be performed at the temperature of about 1500° C. to about 1600° C. More preferably, the surface treatment process may be performed at the temperature of about 1500° C. to about 1600° C. for about 5 minutes.

In addition, during the surface treatment process, the pressure in the susceptor may be about 50 mbar or more. More specifically, pressure in the susceptor may be in the range of about 50 mbar to about 100 mbar.

Normally, a silicon carbide bulk silicon wafer has a rough surface since uneven patterns may be formed on the surface thereof due to silicon (Si) on the surface of the silicon carbide bulk silicon wafer. Such a surface roughness may generate defects on the silicon carbide wafer, and accordingly, the defects may affect the silicon carbide epi-layer when the silicon carbide epi-layer is deposited on the silicon carbide wafer.

The surface defects may be droplets, triangle defects, pits, wavy pits, or particles.

However, the surface defects and the surface roughness may be reduced by the surface treatment process according to the embodiment of the present invention. That is, unstable Si atoms on the surface of the wafer may be controlled by heating the silicon carbide wafer to a temperature of about 1500° C. to about 1600° C. and maintaining the pressure in the susceptor within the range of about 50 mbar to about 100 mbar during the surface treatment process.

Accordingly, by controlling the unstable Si atoms on the surface of the wafer, the surface defects, step bunching, or the surface roughness generated while the epi-layer is grown on the wafer may be reduced. According to the method of fabricating an epi-wafer according to the embodiment of the present invention, the surface defects, the step bunching, or the surface roughness may be reduced by performing the surface treatment process on the wafer. Thus, a high-quality silicon carbide epi-wafer may be fabricated.

Next, the process of growing the epi-layer on the wafer (ST30) includes growing the epi-layer on the surface-treated wafer. Here, the epi-layer may be a silicon carbide epi-layer.

The process of growing the epi-layer on the wafer (ST30) may include depositing the epi-layer on the wafer using a deposition apparatus including the susceptor.

FIGS. 2 to 4 are diagrams respectively illustrating an exploded perspective view, a perspective view, and a cross-sectional view of a susceptor for describing a method of fabricating an epi-wafer according to the embodiment of the present invention.

Referring to FIGS. 2 to 4, the deposition apparatus includes a chamber 10, a susceptor 20, a source gas line 40, a wafer holder 30, and an induction coil 50. The chamber 10 may have a cylindrical tube shape. Otherwise, the chamber 10 may have a rectangular box shape. The chamber 10 may accommodate the susceptor 20, the source gas line 40, and the wafer holder 30.

In addition, both ends of the chamber 10 may be closed, and external gases may be prevented from flowing into the chamber 10 to maintain a vacuum state. The chamber 10 may include quartz having high mechanical strength and superior chemical endurance. Further, the chamber 10 may have an improved thermal resistance.

In addition, the chamber 10 may further include an insulation unit 60. The insulation unit 60 may function to maintain heat in the chamber 10. Nitride ceramics, carbide ceramics, or graphite may be exemplarily used as the insulation unit 60.

The susceptor 20 may be disposed in the chamber 10. The susceptor 20 may accommodate the source gas line 40 and the wafer holder 30. In addition, the susceptor 20 may accommodate a substrate such as the wafer W Further, the reaction gas may flow into the susceptor 20 through the source gas line 40.

As illustrated in FIG. 2, the susceptor 20 may include a susceptor top plate 21, a susceptor bottom plate 22, and susceptor side plates 23. In addition, the susceptor top plate 21 may be disposed to face the susceptor bottom plate 22. The susceptor 20 may be fabricated by disposing the susceptor top plate 21 and the susceptor bottom plate 22, disposing the susceptor side plates 23 at both sides thereof, and bonding the susceptor top plate 21, the susceptor bottom plate 22, and the susceptor side plates 23.

However, the present invention is not limited thereto, and the susceptor 20 may be produced by forming a space for a gas path in the rectangular susceptor 20.

The susceptor 20 may include graphite which has high thermal resistance and is easy to process. In addition, the susceptor 20 may have a structure in which a graphite body is coated with silicon carbide. Further, the susceptor 20 may be heated by induction.

The reaction gas, that is a material supplied to the susceptor 20, may be decomposed into an intermediate compound by heat, and deposited on the wafer W in the intermediate compound state. For example, the material may include a liquid, gas, or solid material including C and Si. The liquid material may include methyltrichlorosilane (MTS) or trichlorosilane (TCS). The gas material may include silane (SiH₄), ethylene (C₂H₄), and HCl, or silane, propane (C₃H₈), and HCl. In addition, H₂ may be further included as a carrier gas.

The material may be decomposed into radicals including Si, C, or Cl, and the silicon carbide epi-layer may be grown on the wafer W. More specifically, the radicals may be CHₓ (1≦x<4) or SiClₓ (1≦x<4) including CH₃, SiCl₂, SiCl, SiHCl₂, or the like.

Here, the ratio of C, Si, Cl, and H included in the intermediate compound may be controlled to be constant. More preferably, the mole ratio of C to Si (C/Si) may be in the range of 0.7 to 1, and the mole ratio of Si to H (Si/H) may be in the range of 0.03 to 0.45.

The source gas line 40 may have a rectangular tube shape. A material used as the source gas line 40 may be, for example, quartz.

The wafer holder 30 may be disposed in the susceptor 20. More specifically, the wafer holder 30 may be disposed behind the susceptor 20 in a direction in which the source gas flows. The wafer holder 30 supports the wafer W. A material used as the wafer holder 30 may be, for example, SiC or graphite.

The induction coil 50 may be disposed on an outer side of the chamber 10. More specifically, the induction coil 50 may surround an outer circumference of the chamber 10. The induction coil 50 may heat the susceptor 20 by electromagnetic induction. The induction coil 50 may be wound around the outer circumference of the chamber 10.

The susceptor 20 may be heated to a temperature of about 1500° C. to about 1700° C. by the induction coil 50. That is, the susceptor 20 may be heated to a growth temperature of the epi-layer by the induction coil 50. Next, the source gas may be decomposed into the intermediate compound at the temperature of 1500° C. to 1700° C. and flow into the susceptor to be sprayed on the wafer W. The silicon carbide epi-layer may be formed on the wafer W by the sprayed radicals.

In such a manner, a thin film such as the epi-layer may be formed in the silicon carbide epi-layer deposition apparatus according to the embodiment of the present invention, and remaining gases may be discharged through a discharge line disposed on an ending portion of the susceptor 20.

As described above, in the method of fabricating an epi-wafer according to the embodiment of the present invention, surface defects and surface roughness may be reduced by controlling unstable Si atoms on the surface of the wafer through a surface treatment process on the wafer. In particular, a high quality silicon carbide epi-wafer having the surface defects of 0.5 ea/cm² or less and a surface roughness of 1.0 nm or less may be fabricated through the method of fabricating an epi-wafer according to the embodiment of the present invention.

That is, according to the method of fabricating an epi-wafer according to the embodiment of the present invention, a silicon carbide epi-wafer including a wafer and an epi-layer formed on the wafer and having surface defects of 0.5 ea/cm² or less and a surface roughness of 1.0 nm or less may be fabricated.

Hereinafter, embodiments of the present invention will be described in more detail using methods of fabricating a silicon carbide epi-wafer according to Embodiments and Comparative Examples. Such manufacturing examples are only examples for describing the embodiments of the present invention in more detail, and accordingly the present invention is not limited thereto.

### Embodiment

A silicon carbide wafer was disposed in a susceptor, and HCl gas was supplied into the susceptor. Here, a flow rate of the HCl was in the range of about 100 ml to about 500 ml per minute. Next, the susceptor was heated to a temperature of 1500° C. to 1600 C, and a heat treatment process in which a surface of wafer was etched under a pressure of 50 mbar to 100 mbar for about 5 minutes was performed.

Next, silane, propane, HCl, and H₂ were supplied as source gases, and a reaction was carried out at about 1600° C. to grow a silicon carbide epi-layer on the silicon carbide wafer.

### Comparative Example

A silicon carbide epi-wafer was fabricated using the same method as the Embodiment 1, except that a surface treatment was not carried out.

TABLE 1

| | Surface Defects (ea/cm²) | Roughness (nm) |
|---|---|---|
| Embodiment | Less than 0.5 | Less than 1 |
| Comparative Example | More than 0.5 | More than 1 |

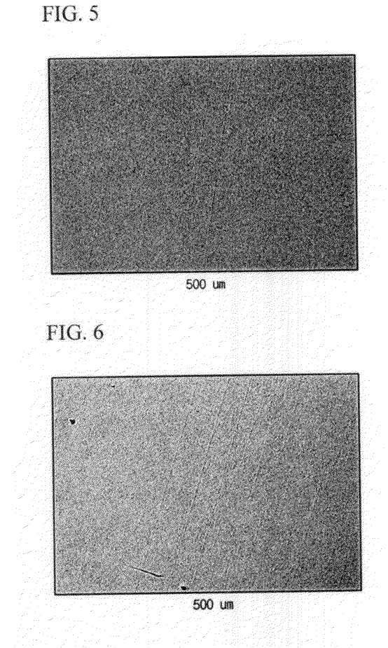

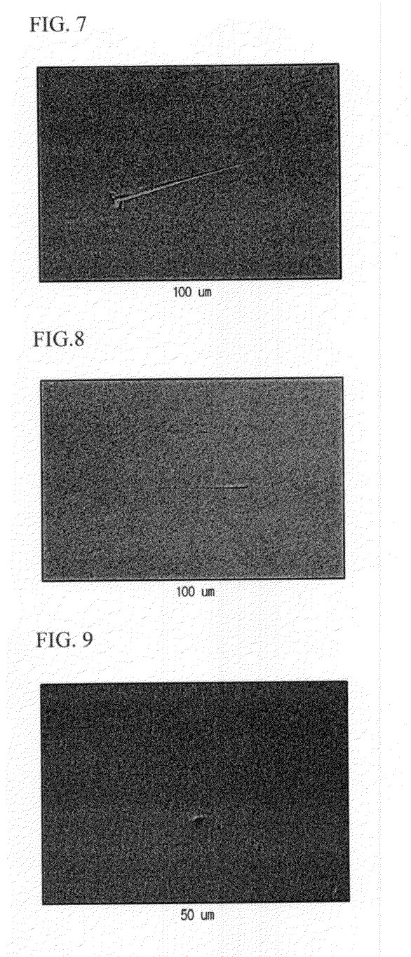

Referring to Table 1 and FIGS. 5 to 9, the silicon carbide epi-wafer fabricated after the surface treatment process had smaller surface defects and surface roughness than the silicon carbide epi-wafer fabricated with no surface treatment process. FIGS. 5 to 8 are SEM photographs of the silicon carbide epi-wafer fabricated after the surface'treatment process, and FIG. 9 is a SEM photograph of the silicon carbide epi-wafer fabricated with no surface treatment process. More specifically, FIG. 5 is an epi-wafer surface-treated under a pressure of 50 mbar, FIG. 6 is an epi-wafer surface-treated under a pressure of 100 mbar, FIG. 7 is an epi-wafer surface-treated while supplying HCl gas at a flow rate of 200 ml/min, and FIG. 8 is an epi-wafer surface-treated while supplying HCl gas at a flow rate of 500 ml/min.

Accordingly, referring to Table 1 and FIGS. 5 to 9, surface defects and surface roughness of the wafer may be reduced by the surface treatment process. That is, silicon on the surface of the silicon carbide bulk wafer may form protrusions on the surface of the silicon carbide wafer and roughen the surface of the silicon carbide wafer. Such surface roughness may cause generation of defects on the silicon carbide wafer, and the defects may remain when the silicon carbide epi-layer is deposited on the silicon carbide wafer and affect the silicon carbide epi-layer.

Accordingly, unstable Si atoms on the surface of the wafer may be suppressed by the surface treatment process on the wafer according to the embodiment of the present invention. In the method of fabricating a silicon carbide epi-wafer according to the embodiment of the present invention and the silicon carbide epi-wafer fabricated using the method, the surface defects, the step bunching, or the surface roughness generated while the epi-layer is grown on the wafer may be reduced by suppressing the Si atoms on the surface of the wafer using the etching process using the surface treatment gas. In particular, the surface defects may be reduced to less than 0.5 ea/cm², and the surface roughness may be reduced to less than 1 nm in the method of fabricating an epi-wafer according to the embodiment of the present invention, a high quality silicon carbide epi-wafer may be fabricated, and the epi-wafer according to the embodiment of the present invention may be used as an electronic material having high quality and high efficiency.

The characteristics, structures, and effects of the above-described embodiment may be applied to at least one embodiment, and are not limited to the one embodiment. Further, the characteristics, structures, and effects of the above-described embodiment may be combined with other embodiments or modified by one of ordinary skill in the art to which this invention belongs.

Those descriptions related to such combinations and modifications should be interpreted as being included in the scope of the embodiments of the present invention.

It will be apparent to those skilled in the art that various modifications can be made to the above-described exemplary embodiments of the present invention without departing from the spirit or scope of the invention. Thus, it is intended that the present invention cover all such modifications provided they come within the scope of the appended claims and their equivalents.

1. An epi-wafer comprising:
a wafer; and
an epi-layer formed on the wafer,
wherein surface defects of the wafer are 0.5 ea/cm² or less.

2. The epi-wafer of claim 1, wherein the surface defects are one of droplets, triangle defects, pits, wavy pits, and particles.

3. The epi-wafer of claim 1, wherein surface roughness of the wafer is 1 nm or less.

4. The epi-wafer of claim 1, wherein the wafer or the epi-layer includes silicon carbide.

5. The epi-wafer of claim 4, wherein the wafer is 4H silicon carbide and an off angle thereof is in the range of 3° to 10°.
